(19) United States
(12) Patent Application Publication
(10) Pub. No.: US 2025/0268033 A1
(43) Pub. Date: Aug. 21, 2025

(54) DISPLAY DEVICE

(71) Applicant: Samsung Display Co., LTD., Yongin-si (KR)

(72) Inventors: Ji Hye LEE, Yongin-si (KR); Kyung Bae KIM, Yongin-si (KR); Yong Hee LEE, Yongin-si (KR)

(21) Appl. No.: 18/934,844

(22) Filed: Nov. 1, 2024

(30) Foreign Application Priority Data
Feb. 16, 2024 (KR) 10-2024-0022921

(51) Int. Cl. H10K 59/131

(52) U.S. Cl. CPC H10K 59/131

(57) ABSTRACT

A display device includes a pixel circuit layer, and an anode above the pixel circuit layer, and including a contact area overlapping a contact hole electrically connected with a connection pattern of the pixel circuit layer, and a non-contact area that is symmetrical to the contact area.

### CROSS-REFERENCE TO RELATED APPLICATION

The present application claims priority to, and the benefit of, Korean Patent Application No. 10-2024-0022921, filed on Feb. 16, 2024, the entire disclosure of which is incorporated herein by reference.

### BACKGROUND

### 1. Field

Aspects of embodiments of the present disclosure relate to a display device.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

### SUMMARY

### Embodiments of the present disclosure provide a display device capable of removing a difference in reflective color between areas.

According to embodiments of the present disclosure, a display device includes a pixel circuit layer, and an anode above the pixel circuit layer, and including a contact area overlapping a contact hole electrically connected with a connection pattern of the pixel circuit layer, and a non-contact area that is symmetrical to the contact area.

A surface area and a shape of the non-contact area may be substantially identical to a surface area and a shape of the contact area.

In a plan view, the contact area may be positioned in a 6 o'clock direction, and the non-contact area is positioned in a 12 o'clock direction.

In a plan view, the contact area may be positioned in a 12 o'clock direction, and the non-contact area is positioned in a 6 o'clock direction.

The anode further may include an exposure area corresponding to a shape of an emission area.

The shape of the emission area may be substantially hexagonal.

There might be no contact hole below the non-contact area.

According to embodiments of the present disclosure, a display device includes a first anode including a first contact area overlapping a first contact hole electrically connected to a connection pattern of a first pixel circuit layer, and a first non-contact area that is symmetrical to the first contact area, a second anode including a second contact area overlapping a second contact hole electrically connected to a connection pattern of a second pixel circuit layer, and a second non-contact area that is symmetrical to the second contact area, and a third anode including a third contact area overlapping a third contact hole electrically connected to a connection pattern of a third pixel circuit layer, and a third non-contact area that is symmetrical to the third contact area.

The first pixel circuit layer, the second pixel circuit layer, and the third pixel circuit layer may be arranged in a row direction.

The first anode and the third anode may be arranged in the row direction, and the second anode is arranged in a diagonal direction from the first anode or the third anode.

The first contact area, the second contact area, and the third contact area may be arranged in a same row.

In a plan view, the first contact area and the third contact area may be positioned in a 6 o'clock direction, and the second contact area is positioned in a 12 o'clock direction.

In a plan view, the first non-contact area and the third non-contact area may be positioned in the 12 o'clock direction, and the second non-contact area is positioned in the 6 o'clock direction.

In a plan view, the first contact area and the third contact area may be positioned in a 12 o'clock direction, and the second contact area is positioned in a 6 o'clock direction.

In a plan view, the first non-contact area and the third non-contact area may be positioned in the 6 o'clock direction, and the second non-contact area is positioned in the 12 o'clock direction.

The first non-contact area, the second non-contact area, and the third non-contact area may be arranged in a same row.

In a plan view, the first non-contact area and the third non-contact area may be positioned in a 12 o'clock direction, and the second non-contact area is positioned in a 6 o'clock direction.

In a plan view, the first contact area and the third contact area may be positioned in a 6 o'clock direction, and the second contact area is positioned in a 12 o'clock direction.

In a plan view, the first non-contact area and the third non-contact area may be positioned in a 6 o'clock direction, and the second non-contact area is positioned in a 12 o'clock direction.

In a plan view, the first contact area and the third contact area may be positioned in the 12 o'clock direction, and the second contact area is positioned in the 6 o'clock direction.

### BRIEF DESCRIPTION OF THE DRAWINGS

The above and other aspects of the present disclosure will become more apparent by describing, in further detail, embodiments thereof with reference to the accompanying drawings, in which:

FIG. 1 is a block diagram of a display device in accordance with one or more embodiments.

FIG. 2 is a block diagram of a sub-pixel in accordance with one or more embodiments.

FIG. 3 is a plan view of a display panel in accordance with one or more embodiments.

FIG. 4 is a sectional view of a display panel in accordance with one or more embodiments.

FIGS. 5 and 6 are plan views of a first pixel of FIG. 3 in accordance with one

or more embodiments.

FIGS. 7 and 8 are plan views of a second pixel of FIG. 3 in accordance with one or more embodiments.

FIG. 9 is a sectional view taking along the line I-I′ of FIG. 6 in accordance with one or more embodiments.

FIGS. 10 to 13 are plan views of anodes in accordance with one or more embodiments.

FIG. 14 is a block diagram of a display system in accordance with one or more embodiments.

FIGS. 15 to 18 are perspective views of applications of a display system of FIG. 14.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be

exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

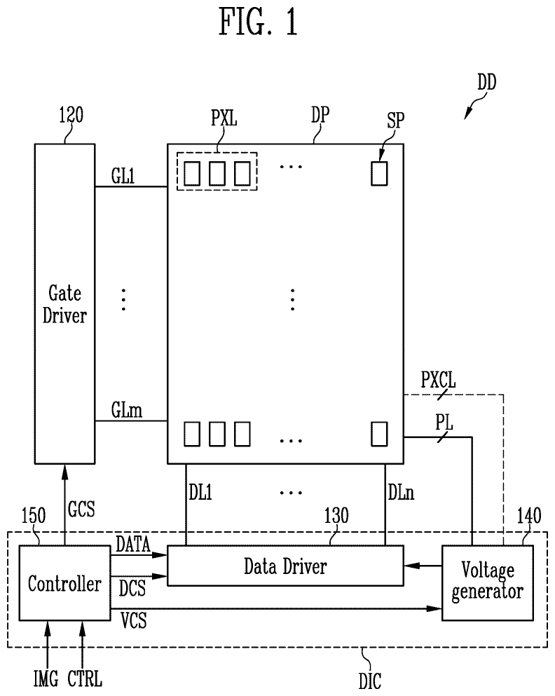

FIG. 1 is a block diagram illustrating a display device 100 in accordance with one or more embodiments.

Referring to FIG. 1, the display device 100 may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light in two or more colors. For example, each of the sub-pixels SP may generate light in a color, such as red, green, blue, cyan, magenta, or yellow.

Two or more sub-pixels among the sub-pixels SP may form one pixel PXL. For example, the pixel PXL may include three sub-pixels, as illustrated in FIG. 1. As such, the pixel PXL may emit light of various colors and various luminances depending on the combination of light emitted from the sub-pixels included therein.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal, and the like.

The gate driver 120 may be located on one side of the display panel DP. However, the embodiments are not limited to the aforementioned example. For example, the gate driver 120 may be divided into two or more drivers that are physically and/or logically distinguished from each other. The drivers may be respectively located on a first side of the display panel DP, and on a second side of the display panel DP that is opposite to the first side. As such, the gate driver 120 may be located around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may be operated in response to the data control signal DCS. In embodiments, the data control signal DCS may include a source start signal, a source shift clock, a source output enable signal, and the like.

The data driver 130 may receive voltages from the voltage generator 140. The data driver 130 may apply, using received voltages, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages, and to provide the generated voltages to components of the display device 100, such as the gate driver 120, the data driver 130, and the controller 150. The voltage generator 140 may receive an input voltage from an external device of the display device 100, and may generate a plurality of voltages by regulating the received voltage.

The voltage generator 140 may generate a first power voltage and a second power voltage. The generated first and second power voltages may be provided to the sub-pixels SP through power lines PL. In other embodiments, at least one of the first or second power voltages may be provided from an external device to the display device 100.

In addition, the voltage generator 140 may provide various voltages and/or signals. For example, the voltage generator 140 may provide one or more initialization voltages to be applied to the sub-pixels SP. For example, during a sensing operation for sensing electrical characteristics of transistors and/or light-emitting elements of the sub-pixels SP, a certain reference voltage may be applied to each of the first to n-th data lines DL1 to DLn. The voltage generator 140 may generate the reference voltage, and may transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although in FIG. 1 there is illustrated the case where the pixel control lines PXCL are connected between the voltage generator 140 and the display panel DP, the embodiments are not limited thereto. For example, the pixel control lines PXCL may be connected between the gate driver 120 and the display panel DP. In this case, the pixel control signals may be transmitted from the gate driver 120 to the sub-pixels SP through the pixel control lines PXCL.

The controller 150 may control overall operations of the display device 100. The controller 150 may receive input image data IMG and a corresponding control signal CTRL from an external device. The controller 150 may provide a gate control signal GCS, a data control signal DCS, and a voltage control signal VCS, in response to the control signal CTRL.

The controller 150 may convert the input image data IMG to be suitable for the display device 100 or the display panel DP and then output image data DATA. In embodiments, the controller 150 may align the input image data IMG to be suitable for the sub-pixels SP on a row basis, and then may output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, or the controller 150 may be provided as a component separated from the driver integrated circuit DIC.

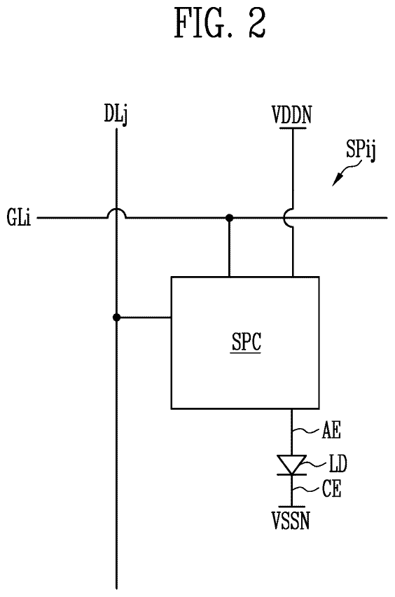

FIG. 2 is a block diagram of a sub-pixel in accordance with one or more

embodiments. In FIG. 2, there is illustrated a sub-pixel SPij located on an i-th row (where i is an integer identical to or greater than 1 and identical to or less than m) and a j-th column (where j is an integer identical to or greater than 1 and identical to or less than n) among the sub-pixels SP of FIG. 1.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. The first power voltage may have a voltage level that is higher than the second power voltage.

The light-emitting element LD may be connected between an anode AE and a cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light-emitting element LD may be configured to emit light based on current flowing from the anode AE to the cathode CE.

The sub-pixel circuit SPC may be connected both to an i-gate line GLi among the first to m-th gate lines GL1 to GLm of FIG. 1, and to a j-th data line DLj among the first to n-th data lines DL1 to DLn of FIG. 1. In response to a gate signal received through the i-th gate line GLi, the sub-pixel circuit SPC may control the light-emitting element LD to emit light based on a data signal received through the j-th data line DLj. In embodiments, the sub-pixel circuit SPC may be further connected to the pixel control lines PXCL of FIG. 1. In this case, the sub-pixel circuit SPC may further control the light-emitting element LD in response to pixel control signals received through the pixel control lines PXCL.

For the sake of the aforementioned operations, the sub-pixel circuit SPC may include circuit elements, for example, transistors and one or more capacitors.

The transistors of the sub-pixel circuit SPC may include p-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, or the like.

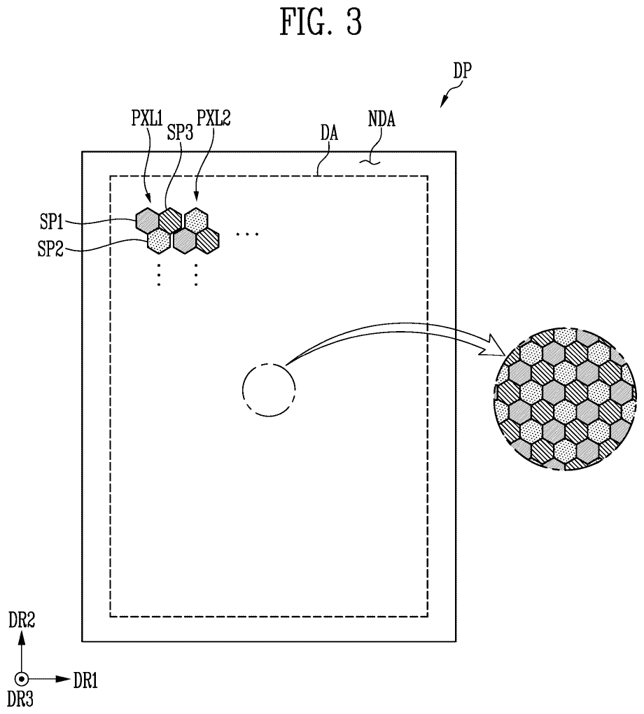

FIG. 3 is a plan view of a display panel in accordance with one or more embodiments.

Referring to FIG. 3, the display panel DP may include a display area DA and a non-display area NDA. The display panel DP may display an image through the display area DA. The non-display area NDA may be located around the display area DA (e.g., in plan view).

First pixels PXL1 and second pixels PXL2 may be located in the display area DA. The first pixels PXL1 and the second pixels PXL2 may be arranged in the first direction DR1, and in the second direction DR2 crossing with the first direction DR1. The first direction DR1 may refer to a row direction, and the second direction DR2 may refer to a column direction. For example, the first pixels PXL1 and the second pixels PXL2 may be alternately arranged based on the first direction DR1. The first pixels PXL1 may be arranged in a line based on the second direction DR2. The second pixels PXL2 may be arranged in a line based on the second direction DR2. However, the arrangement of the first pixels PXL1 and the second pixels PXL2 is not limited to the aforementioned example. For example, the first pixels PXL1 and the second pixels PXL2 may be arranged in a zigzag pattern in the first direction DR1 and in the second direction DR2.

Two or more sub-pixels among the sub-pixels may form one first pixel PXL1. For example, the first pixel PXL1 may include a first sub-pixel SP1, a second sub-pixel SP2, and a third sub-pixel SP3. Furthermore, two or more sub-pixels among the sub-pixels may form one second pixel PXL2. For example, the second pixel PXL2 may include a first sub-pixel SP1, a second sub-pixel SP2, and a third sub-pixel SP3. However, the embodiments are not limited thereto. In one or more embodiments, each of the first pixel PXL1 and the second pixel PXL2 may include two sub-pixels. Hereinafter, for convenience of explanation, it is assumed that each of the first pixel PXL1 and the second pixel PXL2 includes first to third sub-pixels SP1, SP2, and SP3.

In each of the first and second pixels PXL1 and PXL2, the first sub-pixel SP1 and the third sub-pixels SP3 may be arranged in the same row, and the second sub-pixel SP2 may be arranged in a row that is different from the first sub-pixel SP1 and the third sub-pixel SP3. The second sub-pixel SP2 may be arranged in a diagonal direction(s) based on the first sub-pixel SP1 and the third sub-pixel SP3. The first pixel PXL1 and the second pixel PXL2 may be vertically symmetrical to each other. For example, the first sub-pixel SP1 and the third sub-pixel SP3 of the first pixel PXL1 may be arranged in the same row as the second sub-pixel SP2 of the second pixel PXL2. The second sub-pixel SP2 of the first pixel PXL1 may be arranged in the same row as the first sub-pixel SP1 and the third sub-pixel SP3 of the second pixel PXL2.

Each of the first to third sub-pixels SP1, SP2, and SP3 may generate light of one among various colors, such as red, green, blue, cyan, magenta, and yellow. Hereinafter, for clear and concise description, it is assumed that the first sub-pixel SP1 is configured to generate light in red, the second color pixel SP2 is configured to generate light in green, and the third sub-pixel SP3 is configured to generate light in blue.

Each of the first to third sub-pixels SP1, SP2, and SP3 may include at least one light-emitting element configured to generate light. In embodiments, the light-emitting elements of the first to third sub-pixels SP1, SP2, and SP3 may generate light in different colors. For example, the light-emitting elements of the first to third sub-pixels SP1, SP2, and SP3 may respectively generate light in red, green, and blue.

As a display panel DP, a self-luminous display panel, such as an LED display panel using a micro-scale or nano-scale light-emitting diode as a light-emitting element, and an organic light-emitting display panel (OLED panel) using an organic light-emitting diode as a light-emitting element may be used.

In the non-display area NDA, components for controlling the first pixels PXL1 and the second pixels PXL2 may be located. Lines connected to the first pixels PXL1 and the second pixels PXL2, for example, the first to m-th gate lines GL1 to GLm, the first to n-th data lines DL1 to DLn, the power lines PL, and the pixel control lines PXCL of FIG. 1, may be located in the non-display area NDA.

At least one of the gate driver 120, the data driver 130, the voltage generator 140, and the controller 150 of FIG. 1 may be located in the non-display area NDA of the display panel DP. In embodiments, the gate driver 120 may be located in the non-display area NDA. In this case, the data driver 130, the voltage generator 140, and the controller 150 may be implemented as the driver integrated circuit DIC of FIG. 1 that is separated from the display panel DP. The driver integrated circuit DIC may be connected to the lines located in the non-display area NDA. In other embodiments, the gate driver 120 along with the data driver 130, the voltage generator 140, and the controller 150 may be implemented as a single integrated circuit that is separated from the display panel DP.

In embodiments, the display area DA may have various shapes. The display area DA may have a closed-loop shape, including linear and/or curved sides. For example, the display area DA may have shapes, such as polygons, circles, semicircles, ellipses, and the like.

In embodiments, the display panel DP may have a planar display surface. In embodiments, the display panel DP may have a display surface that is at least partially rounded. In embodiments, the display panel DP may be bendable, foldable, or rollable. In the aforementioned cases, the display panel DP and/or a substrate of the display panel DP may include materials having flexible properties.

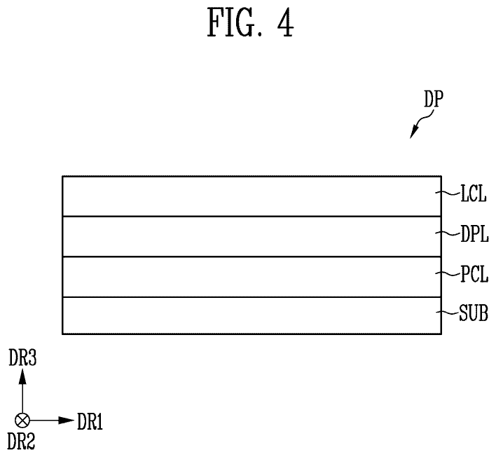

FIG. 4 is a sectional view of a display panel in accordance with one or more embodiments.

Referring to FIG. 4, the display panel DP may include a substrate SUB, and a pixel circuit layer PCL, a display panel layer DPL, and a light conversion layer LCL that are sequentially stacked on the substrate SUB in a third direction DR3 crossing with the first and second directions DR1 and DR2.

The substrate SUB may be made of insulating material, such as glass or resin. For example, the substrate SUB may include a glass substrate. As another example, the substrate SUB may include a polyimide (PI) substrate. As another example, the substrate SUB may include a silicon wafer substrate formed through a semiconductor process.

In embodiments, the substrate SUB may be made of material having flexibility so as to be bendable or foldable, and may have a single-layer structure or a multilayer structure. For instance, the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, the embodiments are not limited thereto.

The pixel circuit layer PCL may be located on the substrate SUB (as used herein, “located on” may mean “above”). The pixel circuit layer PCL may include insulating layers, and semiconductor patterns and conductive patterns located between the insulating layers. The conductive patterns of the pixel circuit layer PCL may function as circuit elements, lines, or the like.

The circuit elements of the pixel circuit layer PCL may include the respective sub-pixel circuits SPC (refer to FIG. 2) of the first to third sub-pixels SP1, SP2, and SP3 of FIG. 3. For example, the circuit elements of the pixel circuit layer PCL may be provided as transistors and one or more capacitors of the sub-pixel circuit SPC.

The lines of the pixel circuit layer PCL may include lines that are respectively connected to the first to third sub-pixels SP1, SP2, and SP3. The lines of the pixel circuit layer PCL may include various signal lines and/or voltage lines needed to drive the display panel layer DPL.

The display panel layer DPL may be located on the pixel circuit layer PCL. The display panel layer DPL may include light-emitting elements of the first to third sub-pixels SP1, SP2, and SP3.

The light conversion layer LCL may be located on the display panel layer DPL. The light conversion layer LCL may include light conversion patterns having color conversion particles and/or scattering particles. For example, the color conversion particles may include quantum dots. The quantum dots may convert the wavelength (or color) of light emitted from the display panel layer DPL. In embodiments, the light conversion patterns may be omitted.

The light conversion layer LCL may further include a color filter layer including color filters. Each of the color filters may selectively transmit light of a corresponding wavelength (or corresponding color). In embodiments, the color filter layer may be omitted.

A window may be provided on the light conversion layer LCL to protect an exposed surface (or upper surface) of the display panel DP. The window may protect the display panel DP from an external impact. The window may be coupled to the light conversion layer LCL by an optically transparent adhesive (or bonding) agent. The window WD may have a multilayer structure selected from among a glass substrate, a plastic film, and a plastic substrate. The multilayer structure may be formed through a successive process or an adhesion process using an adhesive layer. The entirety or portion of the window may have flexibility.

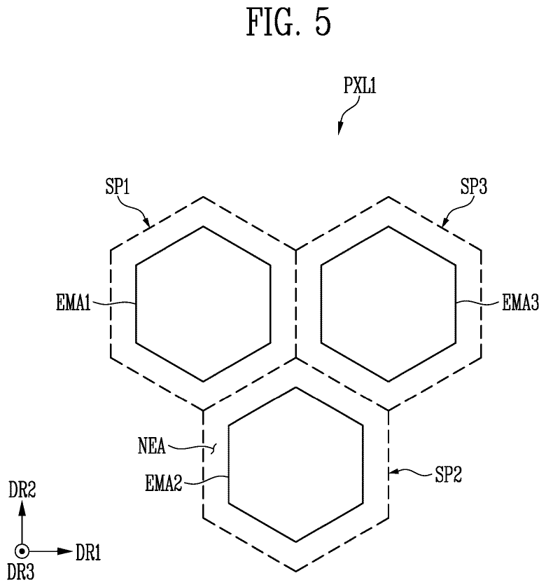

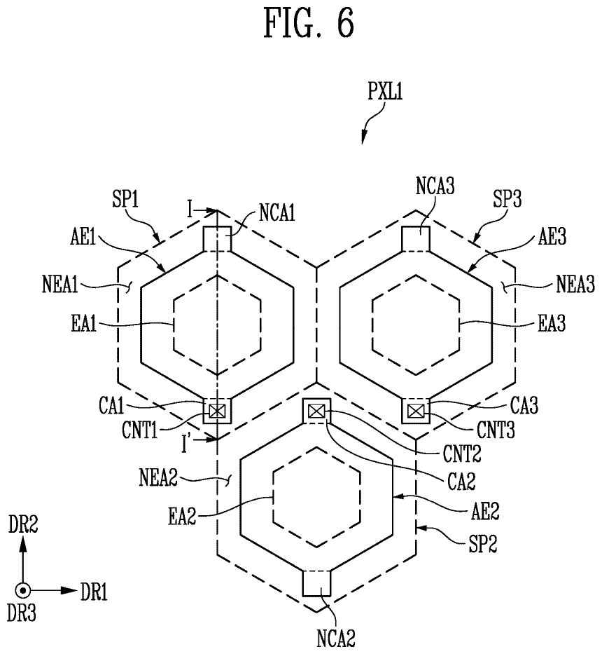

FIGS. 5 and 6 are plan views of a first pixel of FIG. 3 in accordance with one or more embodiments. For convenience of explanation, FIG. 6 illustratively shows first to third anodes AE1, AE2, and AE3 respectively included in the first to third sub-pixels SP1, SP2, and SP3 of the first pixel PXL1.

Referring to FIG. 5, the first pixel PXL1 may include the first sub-pixel SP1, the second sub-pixel SP2, and the third sub-pixel SP3. The first sub-pixel SP1 may include a first emission area EMA1, and a non-emission area NEA formed around the first emission area EMA1. The second sub-pixel SP2 may include a second emission area EMA2, and a non-emission area NEA formed around the second emission area EMA2. The third sub-pixel SP3 may include a third emission area EMA3, and a non-emission area NEA formed around the third emission area EMA3.

Each of the first to third sub-pixels SP1, SP2, and SP3 may have a polygonal shape in the third direction DR3. For example, the shapes of the first to third sub-pixels SP1, SP2, and SP3 may be hexagonal.

Each of the first to third emission areas EMA1, EMA2, and EMA3 may have a polygonal shape in the third direction DR3. For example, the shapes of the first to third emission areas EMA1, EMA2, and EMA3 may be hexagonal. However, the embodiments are not limited thereto. For example, the shapes of the first to third emission areas EMA1, EMA2, and EMA3 may be circular.

The first and third sub-pixels SP1 and SP3 may be arranged in the first direction DR1. The second sub-pixel SP2 may be located in a direction (e.g., a diagonal direction) inclined at an acute angle based on the second direction DR2 with respect to the first and third sub-pixels SP1 and SP3. In the first pixel PXL1, centers of the first to third sub-pixels SP1, SP2, and SP3 may be located at respective vertices of an inverted triangle in a plan view.

The arrangement of the sub-pixels illustrated in FIG. 5 is illustrative, and the embodiments are not limited thereto. Each pixel may include two or more sub-pixels, and the sub-pixels may be arranged in various ways. Each of the sub-pixels may have various shapes. Each of the emission areas of the sub-pixels may also have various shapes.

Referring to FIG. 6, first to third anodes AE1, AE2, and AE3 may be respectively located in the first to third sub-pixels SP1, SP2, and SP3. The first anode AE1 may be provided as the anode AE (refer to FIG. 2) connected to the sub-pixel circuit SPC (refer to FIG. 2) of the first sub-pixel SP1. The second anode AE2 may be provided as the anode AE connected to the sub-pixel circuit SPC of the second sub-pixel SP2. The third anode AE3 may be provided as the anode AE connected to the sub-pixel circuit SPC of the third sub-pixel SP3.

The first anode AE1 may include a first exposure area EA1 and a first non-exposure area NEA1. The second anode AE2 may include a second exposure area EA2 and a second non-exposure area NEA2. The third anode AE3 may include a third exposure area EA3 and a third non-exposure area NEA3.

The first non-exposure area NEA1 may include a first contact area CA1 and a first non-contact area NCA1. For example, portions of the first non-exposure area NEA1 may be defined as the first contact area CA1 and the first non-contact area NCA1. The second non-exposure area NEA2 may include a second contact area CA2 and a second non-contact area NCA2. For example, portions of the second non-exposure area NEA2 may be defined as the second contact area CA2 and the second non-contact area NCA2. The third non-exposure area NEA3 may include a third contact area CA3 and a third non-contact area NCA3. For example, portions of the third non-exposure area NEA3 may be defined as the third contact area CA3 and the third non-contact area NCA3.

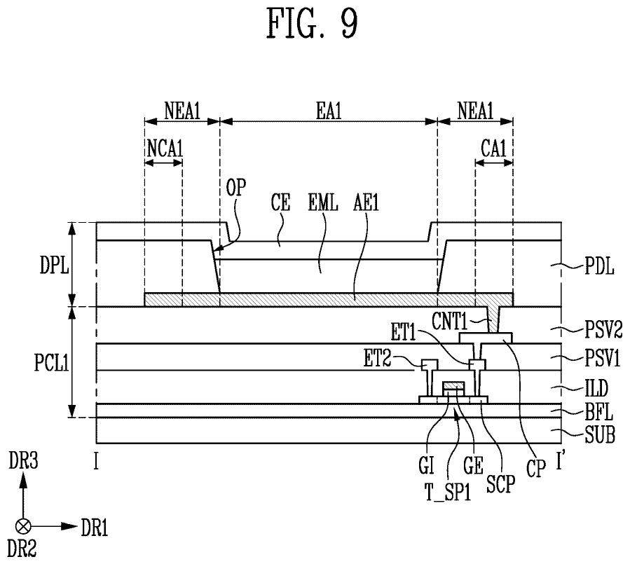

The first exposure area EA1 may be an area where the first anode AE1 is exposed. For example, the first exposure area EA1 of the first anode AE1 may be exposed through an opening OP of the pixel-defining layer PDL (refer to FIG. 9). Likewise, the second exposure area EA2 may be an area where the second anode AE2 is exposed, and the third exposure area EA3 may be an area where the third anode AE3 is exposed.

The first exposure area EA1 may have the same shape as the first emission area EMA1 (refer to FIG. 5). For example, the shape of the first exposure area EA1 may be hexagonal when viewed in the third direction DR3. Likewise, the second exposure area EA2 may have the same shape as the second emission area EMA2 (refer to FIG. 5), and the third exposure area EA3 may have the same shape as the third emission area EMA3 (refer to FIG. 5).

The first non-exposure area NEA1 may be an area where the first anode AE1 is not exposed. The first non-exposure area NEA1 may be covered with other components. For example, the first non-exposure area NEA1 may be covered with the pixel-defining layer PDL without being exposed (refer to FIG. 9). Likewise, the second non-exposure area NEA2 may be an area that is covered with the pixel-defining layer PDL so that the second anode AE2 is not exposed. The third non-exposure area NEA3 may be an area that is covered with the pixel-defining layer PDL so that the third anode AE3 is not exposed.

The first non-exposure area NEA1 may enclose the first exposure area EA1. For example, in the first anode AE1, an area other than the first exposure area EA1 may be the first non-exposure area NEA1. Likewise, the second non-exposure area NEA2 may be provided as an area other than the second exposure area EA2, and may enclose the second exposure area EA2. The third non-exposure area NEA3 may be provided as an area other than the third exposure area EA3, and may enclose the third exposure area EA3.

The first contact area CA1 may be an area including a first contact hole CNT1. A certain area provided to form the first contact hole CNT1 in the first anode AE1 may be defined as the first contact area CA1. Although FIG. 6 illustrates that the first contact area CA1 has a rectangular shape, the embodiments are not limited thereto. For example, the shape and size of the first contact area CA1 may be changed depending on the size, location, and the like of the first contact hole CNT1. Likewise, the second contact area CA2 may be an area including a second contact hole CNT2, and the third contact area CA3 may be an area including a third contact hole CNT3. The shapes and sizes of the second contact area CA2 and the third contact area CA3 may be changed in various ways depending on the sizes, locations, and the like of the second contact hole CNT2 and the third contact hole CNT3.

The first contact area CA1 may correspond to the sub-pixel circuit SPC (refer to FIG. 2) of the first sub-pixel SP1. For example, in a plan view, the first contact area CA1 may be positioned in the 6 o'clock direction, where the first anode AE1 may be electrically connected to the sub-pixel circuit SPC of the first sub-pixel SP1 through the first contact hole CNT1. The second contact area CA2 may correspond to the sub-pixel circuit SPC of the second sub-pixel SP2. For example, in a plan view, the second contact area CA2 may be positioned in the 12 o'clock direction, where the second anode AE2 may be electrically connected to the sub-pixel circuit SPC of the second sub-pixel SP2 through the second contact hole CNT2. The third contact area CA3 may correspond to the sub-pixel circuit SPC of the third sub-pixel SP3. For example, in a plan view, the third contact area CA3 of the third anode AE3 may be positioned in the 6 o'clock direction, where the third anode AE3 may be electrically connected to the sub-pixel circuit SPC of the third sub-pixel SP3 through the third contact hole CNT3. Here, the locations of the first to third contact areas CA1, CA2, and CA3 in the first pixel PXL1 are not limited to the one or more embodiments corresponding to FIG. 6.

In the first pixel PXL1, the first contact area CA1, the second contact area CA2, and the third contact area CA3 may be arranged in the same row. For example, the first to third contact areas CA1, CA2, and CA3 may be arranged in a line in the first direction DR1 (or the row direction). However, the embodiments are not limited thereto.

The first non-contact area NCA1 may be an area that is symmetrical to the first contact area CA1. In the first anode AE1, a certain area that is symmetrical to the first contact area CA1 may be defined as the first non-contact area NCA1. The first non-contact area NCA1 and the first contact area CA1 that are in a symmetrical relationship may have the same shape and/or the same surface area. In this case, light emitted from the light-emitting element LD (refer to FIG. 2) of the first sub-pixel SP1 may be substantially uniformly reflected in the first contact area CA1 and the first non-contact area NCA1. Therefore, with no difference in reflective color between the areas, the reflective color may be substantially uniformly outputted from the first sub-pixel SP1.

The second non-contact area NCA2 may be an area that is symmetrical to the second contact area CA2. In the second anode AE2, a certain area that is symmetrical to the second contact area CA2 may be defined as the second non-contact area NCA2. The second non-contact area NCA2 and the second contact area CA2 that are in a symmetrical relationship may have the same shape and/or the same surface area. In this case, light emitted from the light-emitting element LD (refer to FIG. 2) of the second sub-pixel SP2 may be substantially uniformly reflected in the second contact area CA2 and the second non-contact area NCA2. Therefore, with no difference in reflective color between the areas, the reflective color may be substantially uniformly outputted from the second sub-pixel SP2.

The third non-contact area NCA3 may be an area that is symmetrical to the third contact area CA3. In the third anode AE3, a certain area that is symmetrical to the third contact area CA3 may be defined as the third non-contact area NCA3. The third non-contact area NCA3 and the third contact area CA3 that are in a symmetrical relationship may have the same shape and/or the same surface area. In this case, light emitted from the light-emitting element LD (refer to FIG. 2) of the third sub-pixel SP3 may be substantially uniformly reflected in the third contact area CA3 and the third non-contact area NCA3. Therefore, with no difference in reflective color between the areas, the reflective color may be substantially uniformly outputted from the third sub-pixel SP3.

The first to third non-contact areas NCA1, NCA2, and NCA3 may not include contact holes, such as the first to third contact holes CNT1, CNT2, and CNT3. The first to third non-contact areas NCA1, NCA2, and NCA3 may be formed by changes in design of the first to third anodes AE1, AE2, and AE3 without requiring a complex process. Therefore, differences in reflective color between areas may be easily eliminated (or reduced) without increasing the number of manufacturing processes of the display device DD (refer to FIG. 1) or without lowering the yield thereof.

In the first pixel PXL1, the first to third non-contact areas NCA1, NCA2, and NCA3 may be positioned symmetrically with the first to third contact areas CA1, CA2, and CA3, respectively. For example, in a plan view, the first and third non-contact areas NCA1 and NCA3 may be positioned in the 12 o'clock direction with respect to the first and third contact areas CA1 and CA3, and the second non-contact area NCA2 may be positioned in the 6 o'clock direction with respect to the second contact area CA2. In this case, in the first pixel PXL1, the first non-contact area NCA1 and the third non-contact area NCA3 may be arranged in the same row, and the second non-contact area NCA2 may be arranged in a row that is different from the first non-contact area NCA1 and the third non-contact area NCA3.

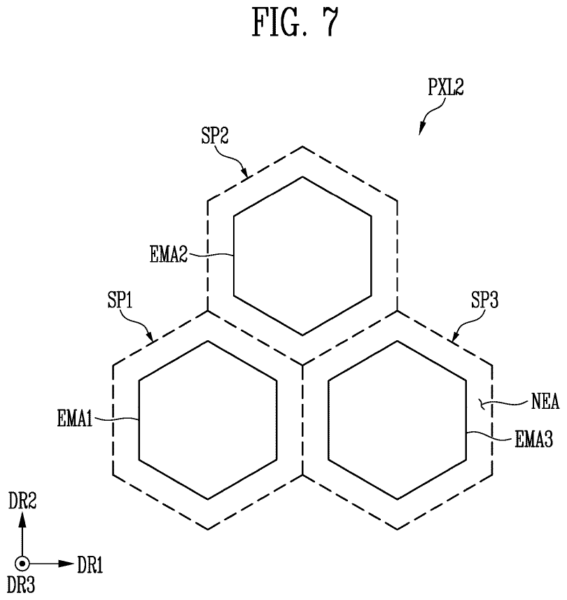

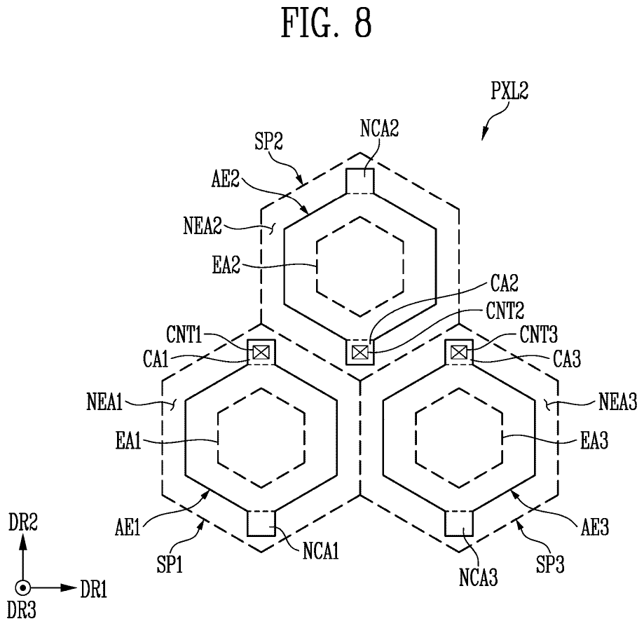

FIGS. 7 and 8 are plan views of a second pixel of FIG. 3 in accordance with one or more embodiments. For convenience of explanation, FIG. 8 illustratively shows first to third anodes AE1, AE2, and AE3 respectively included in the first to third sub-pixels SP1, SP2, and SP3 of the second pixel PXL2. With regard to FIGS. 7 and 8, descriptions of contents overlapping those of FIGS. 5 and 6 will be simplified or omitted.

Referring to FIG. 7, the second pixel PXL2 may include the first sub-pixel SP1, the second sub-pixel SP2, and the third sub-pixel SP3. The first and third sub-pixels SP1 and SP3 may be arranged in the first direction DR1, and the second sub-pixel SP2 may be arranged in a diagonal direction(s) based on the first and third sub-pixels SP1 and SP3. In the second pixel PXL2, centers of the first to third sub-pixels SP1, SP2, and SP3 may be located at respective vertices of an equilateral triangle in a plan view.

Referring to FIG. 8, in a plan view, the first contact area CA1 may be positioned in the 12 o'clock direction, where the first anode AE1 may be electrically connected to the sub-pixel circuit SPC (refer to FIG. 2) of the first sub-pixel SP1 through the first contact hole CNT1. In a plan view, the second contact area CA2 may be positioned in the 6 o'clock direction, where the second anode AE2 may be electrically connected to the sub-pixel circuit SPC of the second sub-pixel SP2 through the second contact hole CNT2. In a plan view, the third contact area CA3 of the third anode AE3 may be positioned in the 6 o'clock direction, where the third anode AE3 may be electrically connected to the sub-pixel circuit SPC of the third sub-pixel SP3 through the third contact hole CNT3. Here, the locations of the first to third contact areas CA1, CA2, and CA3 in the second pixel PXL2 are not limited to the one or more embodiments corresponding to FIG. 8.

In the second pixel PXL2, the first contact area CA1, the second contact area CA2, and the third contact area CA3 may be arranged in the same row. For example, the first to third contact areas CA1, CA2, and CA3 may be arranged in a line in the first direction DR1 (or the row direction). However, the embodiments are not limited thereto.

In the second pixel PXL2, the first to third non-contact areas NCA1, NCA2, and NCA3 may be positioned symmetrically with the first to third contact areas CA1, CA2, and CA3, respectively. For example, in a plan view, the first and third non-contact areas NCA1 and NCA3 may be positioned in the 6 o'clock direction, and the second non-contact area NCA2 may be positioned in the 12 o'clock direction. In this case, in the second pixel PXL2, the first non-contact area NCA1 and the third non-contact area NCA3 may be arranged in the same row, and the second non-contact area NCA2 may be located on a row that is different from the first non-contact area NCA1 and the third non-contact area NCA3.

FIG. 9 is a sectional view taking along the line I-I′ of FIG. 6 in accordance with one or more embodiments.

Referring to FIG. 9, a first pixel circuit layer PCL1 and a display panel layer DPL may be sequentially located on the substrate SUB.

The first pixel circuit layer PCL1 may include insulating layers, semiconductor patterns, and conductive patterns that are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material of copper (Cu), molybdenum (Mo), tungsten (W), aluminum-neodymium (AlNd), titanium (Ti), aluminum (Al), or silver (Ag).

The sub-pixel circuit SPC (refer to FIG. 2) of the first sub-pixel SP1 may include transistors and one or more capacitors. The semiconductor patterns and the conductive patterns included in the first pixel circuit layer PCL1 may function as the transistors and the capacitors of the sub-pixel circuit SPC of the first sub-pixel SP1.

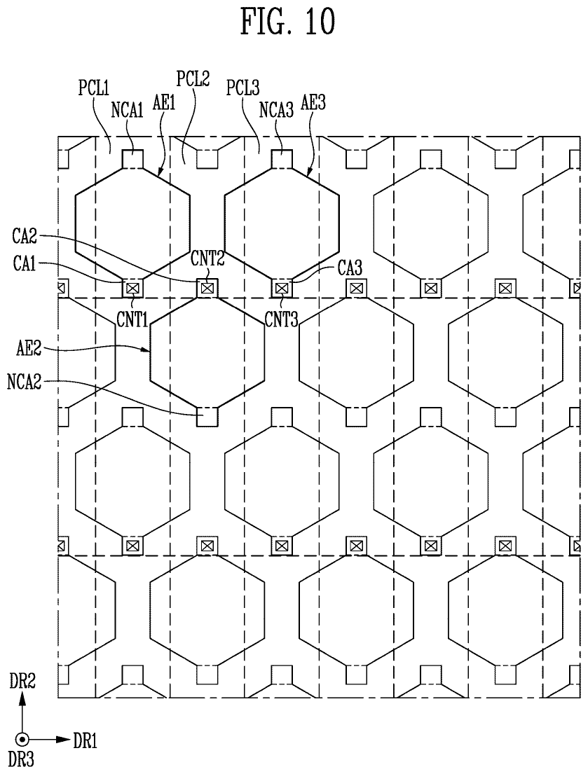

Likewise, the sub-pixel circuit SPC of the second sub-pixel SP2 (refer to FIG. 6) may include transistors and one or more capacitors. Semiconductor patterns and conductive patterns included in a second pixel circuit layer PCL2 (refer to FIG. 10) may function as the transistors and the capacitors of the sub-pixel circuit SPC of the second sub-pixel SP2. Furthermore, the sub-pixel circuit SPC of the third sub-pixel SP3 (refer to FIG. 6) may include transistors and one or more capacitors. Semiconductor patterns and conductive patterns included in a third pixel circuit layer PCL3 (refer to FIG. 10) may function as the transistors and the capacitors of the sub-pixel circuit SPC of the third sub-pixel SP3.

The buffer layer BFL may be located on one surface of the substrate SUB. The buffer layer BFL may reduce or prevent impurities diffusing into the circuit elements and the lines that are included in the pixel circuit layer PCL. The buffer layer BFL may include an inorganic insulating layer including inorganic material. In embodiments, the buffer layer BFL may include at least one of silicon nitride (SiNₓ), silicon oxide (SiOₓ), silicon oxynitride (SiOₓN_{y}), or metal oxide, such as aluminum oxide (AlOₓ). The buffer layer BF may be provided in the form of a single layer or multiple layers. In case that the buffer layer BFL is provided in the form of a multilayer structure, the respective layers may be formed of the same material or different materials.

In embodiments, one or more barrier layers may be located between the substrate SUB and the buffer layer BFL. Each of the barrier layers may include polyimide.

A transistor T_SP1 may be located on the buffer layer BFL. The transistor T_SP1 may be any one of the transistors of the sub-pixel circuit SPC included in the first sub-pixel SP1. For example, it can be understood that the transistor T_SP1 is a transistor connected to the first anode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be either a source electrode or a drain electrode, and the second terminal ET2 may be the other one of the source electrode and the drain electrode. For example, the first terminal ET1 may be a source electrode, and the second terminal ET2 may be a drain electrode.

The semiconductor pattern SCP may be located on the buffer layer BFL. The semiconductor pattern SCP may include a first contact area that contacts the first terminal ET1, and a second contact area that contacts the second terminal ET2. An area between the first contact area and the second contact area may be a channel area. The channel area may overlap the gate electrode GE of the transistor T_SP1. The channel area may be an undoped semiconductor pattern, and may be an intrinsic semiconductor. Each of the first contact area and the second contact area may be a semiconductor pattern doped with an impurity. For example, a p-type impurity may be used as the impurity, but the embodiments are not limited thereto.

The semiconductor pattern SCP may include any one of various types of semiconductors, for example, an amorphous silicon semiconductor, a monocrystalline silicon semiconductor, a polycrystalline silicon semiconductor, a low-temperature polysilicon semiconductor, or an oxide semiconductor.

The interlayer insulating layers ILD that are sequentially stacked may be located on the semiconductor pattern SCP. The interlayer insulating layers ILD may be formed of inorganic insulating layers including inorganic material. For example, each of the interlayer insulating layers ILD may include at least one of silicon nitride (SiNₓ), silicon oxide (SiOₓ), silicon oxynitride (SiOxNy), or metal oxide, such as aluminum oxide (AlOₓ). However, the material of the interlayer insulating layers ILD is not limited to the aforementioned examples. For example, any one of the interlayer insulating layers ILD may include an organic insulating layer including organic material.

The interlayer insulating layers ILD may electrically separate the conductive patterns and/or semiconductor patterns, which are located between the interlayer insulating layers ILD, from each other. For example, the interlayer insulating layers ILD may include a gate-insulating layer GI located on the semiconductor pattern SCP. The gate-insulating layer GI may be located between the semiconductor pattern SCP and the gate electrode GE such that the gate electrode GE is spaced apart from the semiconductor pattern SCP. In embodiments, the gate-insulating layer GI may be located on the overall surfaces of the semiconductor pattern SCP and the buffer layer BFL, thus covering the semiconductor pattern SCP and the buffer layer BFL. As the number of layers needed to form the conductive patterns and/or the semiconductor layers increases, the number of interlayer insulating layers ILD may increase.

The gate electrode GE may be located on/above the gate-insulating layer GI. The gate electrode GE may overlap the channel area of the semiconductor pattern SCP. In embodiments, the gate electrode GE may be provided in the form of a single layer including at least one material of copper (Cu), molybdenum (Mo), tungsten (W), aluminum-neodymium (AlNd), titanium (Ti), aluminum (Al), or silver (Ag). In embodiments, the gate electrode GE may be provided in the form of a multilayer structure including at least one material of molybdenum (Mo), titanium (Ti), copper (Cu), aluminum (Al), or silver (Ag) that are low-resistance materials.

The first and second terminals ET1 and ET2 may be located on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material of copper (Cu), molybdenum (Mo), tungsten (W), aluminum-neodymium (AlNd), titanium (Ti), aluminum (Al), or silver (Ag).

Although the first and second terminals ET1 and ET2 are illustrated as separate electrodes electrically connected to the semiconductor pattern SCP, embodiments are not limited thereto. In embodiments, the first terminal ET1 may be a first contact area adjacent to one side of the channel area of the semiconductor pattern SCP, and the second terminal ET2 may be a second contact area adjacent to the other side of the channel area. In this case, the first terminal ET1 may be electrically connected to the light-emitting element LD through a connector, such as a bridge electrode located on at least one of the interlayer insulating layers ILD.

In embodiments, the transistor T_SP1 may be formed of a low-temperature polysilicon transistor. However, the embodiments are not limited to the aforementioned example. For example, the transistor T_SP1 may be formed of an oxide semiconductor transistor. In embodiments, the sub-pixel circuit of the first sub-pixel SP1 may include different types of transistors. For example, the transistor T_SP1 may be formed of a low-temperature polysilicon transistor. The other transistors of the first sub-pixel SP1 may be formed of oxide semiconductor transistors. In this case, an oxide semiconductor of the corresponding oxide semiconductor transistor may be located on any one of the interlayer insulating layers ILD rather than on an insulating layer on which the semiconductor pattern SCP of the transistor T_SP1 is located.

Although in the embodiments there has been described the case where the transistor T_SP1 has a top gate structure, the embodiments are not limited thereto. For example, the transistor T_SP1 may be a transistor having a bottom gate structure. In addition, the structure of the transistor T_SP1 may be changed in various ways.

The first passivation layer PSV1 may be located on the transistor T_SP1. The passivation layer may be referred to as a protective layer or a via layer. The first passivation layer PSV1 may protect components located thereunder, and may provide an even upper surface.

A connection pattern CP1 may be located on the first passivation layer PSV1. The connection pattern CP may pass through the first passivation layer PSV1, and may be connected to the first terminal ET1 of the transistor T_SP1. The connection pattern CP may include at least one material of copper (Cu), molybdenum (Mo), tungsten (W), aluminum-neodymium (AlNd), titanium (Ti), aluminum (Al), or silver (Ag).

The first contact hole CNT1 may be positioned on the connection pattern CP. One end of the first contact hole CNT1 may pass through the second passivation layer PSV2, and may be connected to the connection pattern CP. A remaining end of the first contact hole CNT1 may be connected to the first anode AE1. An electrical signal from the transistor T_SP1 may be provided to the first anode AE1 via the first contact hole CNT1. The first contact hole CNT1 may have the same material as the first anode AE1, but the present embodiments are not limited thereto.

The second passivation layer PSV2 may be located on the connection pattern CP and the first passivation layer PSV1. The second passivation layer PSV2 may protect components located thereunder, and may provide an even upper surface.

Each of the first and second passivation layers PSV1 and PSV2 may include an inorganic insulating layer including inorganic material, and/or an organic insulating layer including organic material. The inorganic insulating layer may include, for example, at least one of silicon oxide (SiOₓ), silicon nitride (SiNₓ), silicon oxynitride (SiOxNy), or metal oxide, such as aluminum oxide (AlOₓ). The organic insulating layer may include, for example, at least one of acrylic resin, epoxy resin, phenolic resin, polyamide resin, polyimide rein, unsaturated polyester resin, poly-phenylen ether resin, poly-phenylene sulfide resin, or benzocyclobutene resin.

The first and second passivation layers PSV1 and PSV2 may include the same material as any one of the interlayer insulating layers ILD, but the embodiments are not limited thereto. Each of the first and second passivation layers PSV1 and PSV2 may be provided in the form of a single-layer structure, but may be provided in the form of a multilayer structure.

The display panel layer DPL may be located on the second passivation layer PAS2. The display panel layer DPL may include a first anode AE1, a pixel-defining layer PDL, an emission layer EML, and a cathode CE.

The first anode AE1 may be located on the first pixel circuit layer PCL1. The first anode AE1 may include at least one of transparent conductive materials, such as indium tin oxide (ITO), indium zinc oxide (IZO), zinc oxide (ZnOₓ), indium gallium zinc oxide (IGZO), or indium tin zinc oxide (ITZO). However, the embodiments are not limited to the aforementioned example. For example, the first anode AE1 may include titanium nitride.

The first anode AE1 may include a first contact area CA1 for electrical connection with the transistor T_SP1. The first anode AE1 may be electrically connected to the transistor T_SP1 through the first contact hole CNT1 included in (or overlapped with) the first contact area CA1.

The first anode AE1 may include a first non-contact area NCA1 for control of the reflective color. The first non-contact area NCA1 may have the same shape and surface area as the first contact area CA1 so as to be symmetrical to the first contact area CA1. Light emitted from the emission layer EML may be substantially uniformly reflected and outputted from the first contact area CA1 and the first non-contact area NCA1. Accordingly, differences in reflective color between areas may be eliminated (or reduced). There might be no contact hole, such as the first contact hole CNT1, below the first non-contact area NCA1.

The pixel-defining layer PDL may be located on the first anode AE1 (e.g., on an edge portion) and on the second passivation layer PSV2. For example, the pixel-defining layer PDL may be located on the first non-exposure area NEA1 of the first anode AE1. The pixel-defining layer PDL may include, or define, an opening OP that exposes a portion of the first anode AE1. The first exposure area EA1 of the first anode AE1 may be exposed through the opening OP of the pixel-defining layer PDL. The emission layer EML and the cathode CE may be located in the opening OP of the pixel-defining layer PDL. The first anode AE1, the emission layer EML, and the cathode CE may form the light-emitting element LD (refer to FIG. 2) of the first sub-pixel SP1 (refer to FIG. 6). In other words, the light-emitting element LD may be located in the opening OP of the pixel-defining layer PDL. As such, the pixel-defining layer PDL may define an area where the light-emitting element LD is positioned.

The pixel-defining layer PDL may include inorganic material. In this case, the pixel-defining layer PDL may include a plurality of inorganic layers stacked on top of one another. For example, the pixel-defining layer PDL may include silicon oxide (SiOₓ) and silicon nitride (SiNₓ). In one or more embodiments, the pixel-defining layer PDL may include organic material. However, the material of the pixel-defining layer PDL is not limited to the aforementioned examples.

The emission layer EML may be located at the first exposure area EA1 of the first anode AE1. The emission layer EML may be located in the opening OP of the pixel-defining layer PDL, and may overlap a portion of the first non-exposure area NEA1 of the first anode AE1. Holes injected from the first anode AE1 and electrons injected from the cathode CE may be transported into the emission layer EML to form excitons. Light may be generated when the excitons make a transition from an excited state to a ground state. The luminance of light may be determined based on the amount of current flowing through the emission layer EML. Depending on the configuration of the emission layer EML, the wavelength range of light to be generated may be determined.

The cathode CE may be located on the emission layer EML and the pixel-defining layer PDL. The cathode CE may extend over the first to third sub-pixels SP1, SP2, and SP3 (refer to FIG. 6). As such, the cathode CE may be provided as a common electrode for the first to third sub-pixels SP1, SP2, and SP3.

The cathode CE may be a thin-film metal layer having a thickness allowing light emitted from the emission layer EML to pass therethrough. The cathode CE may be made of a metal material having a relatively small thickness, or a transparent conductive material. For example, the cathode CE may include at least one of various transparent conductive materials including indium tin oxide, indium zinc oxide, indium tin zinc oxide, aluminum zinc oxide, gallium zinc oxide, zinc tin oxide, or gallium tin oxide. For example, the cathode CE may include at least one of silver (Ag), magnesium (Mg), or a compound thereof. However, the material of the cathode electrode CE is not limited to the foregoing example.

An encapsulation layer may be located on the cathode CE. The encapsulation layer may cover the display panel layer DPL and/or the first pixel circuit layer PCL1. The encapsulation layer may reduce or prevent oxygen and/or water or the like penetrating into the display panel layer DPL.

Hitherto, the first pixel circuit layer PCL1 and the display panel layer DPL of the first sub-pixel SP1 (refer to FIG. 6) have been described. The second and/or third sub-pixels SP2 and/or SP3 of FIG. 6 may also be configured in the same manner as the first sub-pixel SP1 unless otherwise described.

FIGS. 10 to 13 are plan views of anodes in accordance with one or more embodiments.

In FIGS. 10 to 13, portions indicated by dashed lines refer to the first to third

pixel circuit layers PCL1, PCL2, and PCL3 that respectively correspond to the first to third anodes AE1, AE2, and AE3. The first to third pixel circuit layers PCL1, PCL2, and PCL3 may be arranged in the form of a stripe in the first direction DR1 and in the second direction DR2.

In FIG. 10, there are illustrated the first to third anodes AE1, AE2, and AE3 corresponding to the first pixel PXL1 of FIG. 6. Referring to FIG. 10, the first contact area CA1 may be positioned in the 6 o'clock direction, where the first anode AE1 may be electrically connected to the first pixel circuit layer PCL1 through the first contact hole CNT1. The second contact area CA2 may be positioned in the 12 o'clock direction, where the second anode AE2 may be electrically connected to the second pixel circuit layer PCL2 through the second contact hole CNT2. The third contact area CA3 may be positioned in the 6 o'clock direction, where the third anode AE3 may be electrically connected to the third pixel circuit layer PCL3 through the third contact hole CNT3. The first to third contact areas CA1, CA2, and CA3 may be arranged in the same row (e.g., in a substantially straight line in the first direction DR1).

The first to third non-contact areas NCA1, NCA2, and NCA3 may be respectively symmetrical to the first to third contact areas CA1, CA2, and CA3. The first non-contact area NCA1 and the third non-contact area NCA3 may be positioned in the 12 o'clock direction, and the second non-contact area NCA2 may be positioned in the 6 o'clock direction.

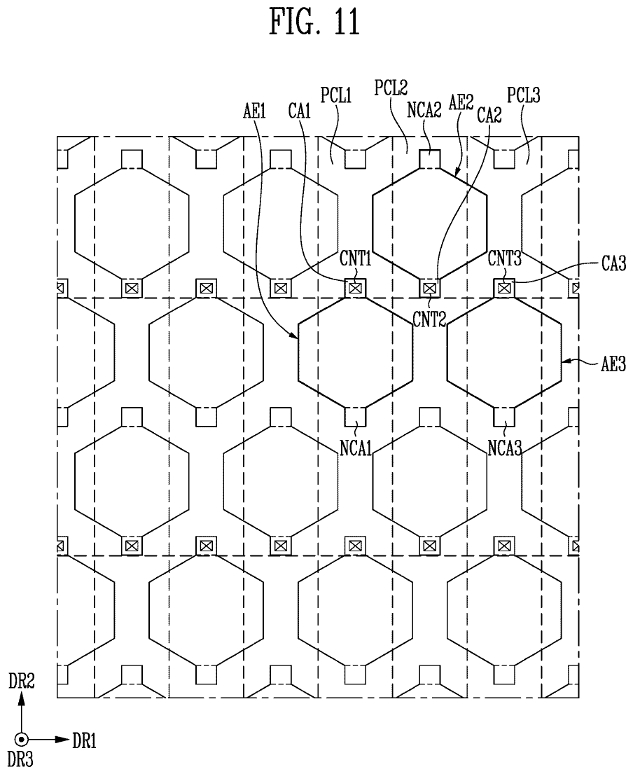

In FIG. 11, there are illustrated the first to third anodes AE1, AE2, and AE3 corresponding to the second pixel PXL2 of FIG. 8. Referring to FIG. 11, the first contact area CA1 may be positioned in the 12 o'clock direction, where the first anode AE1 may be electrically connected to the first pixel circuit layer PCL1 through the first contact hole CNT1. The second contact area CA2 may be positioned in the 6 o'clock direction, where the second anode AE2 may be electrically connected to the second pixel circuit layer PCL2 through the second contact hole CNT2. The third contact area CA3 may be positioned in the 12 o'clock direction, where the third anode AE3 may be electrically connected to the third pixel circuit layer PCL3 through the third contact hole CNT3. The first to third contact areas CA1, CA2, and CA3 may be arranged in the same row.

The first to third non-contact areas NCA1, NCA2, and NCA3 may be respectively symmetrical to the first to third contact areas CA1, CA2, and CA3. The first non-contact area NCA1 and the third non-contact area NCA3 may be positioned in the 6 o'clock direction, and the second non-contact area NCA2 may be positioned in the 12 o'clock direction.

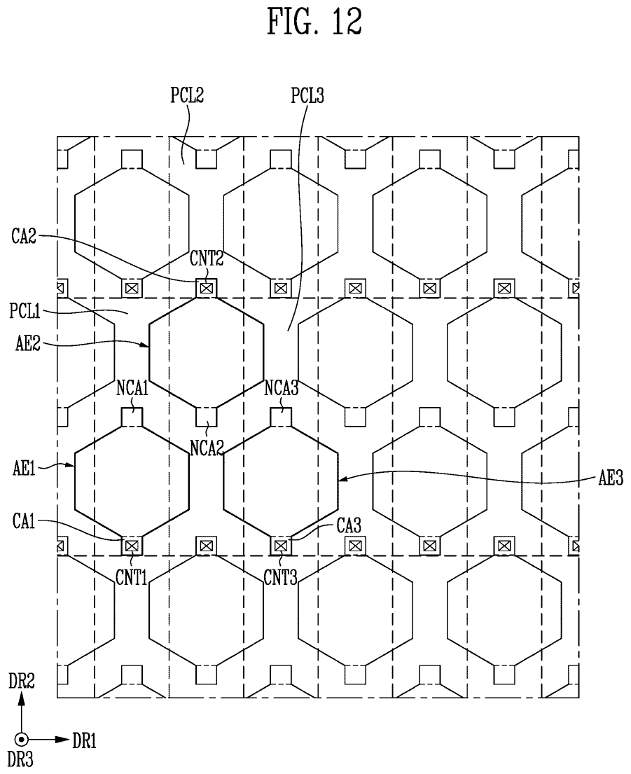

In FIG. 12, there are illustrated the first to third anodes AE1, AE2, and AE3 corresponding to the first pixels PXL1 adjacent to each other. For example, there are illustrated the second anode AE2 of one first pixel PXL1, and the first anode AE1 and the third anode AE3 of an adjacent first pixel PXL1. Referring to FIG. 12, the first contact area CA1 may be positioned in the 6 o'clock direction, where the first anode AE1 may be electrically connected to the first pixel circuit layer PCL1 through the first contact hole CNT1. The second contact area CA2 may be positioned in the 12 o'clock direction, where the second anode AE2 may be electrically connected to the second pixel circuit layer PCL2 through the second contact hole CNT2. The third contact area CA3 may be positioned in the 6 o'clock direction, where the third anode AE3 may be electrically connected to the third pixel circuit layer PCL3 through the third contact hole CNT3.

The first to third non-contact areas NCA1, NCA2, and NCA3 may be respectively symmetrical to the first to third contact areas CA1, CA2, and CA3. The first non-contact area NCA1 and the third non-contact area NCA3 may be positioned in the 12 o'clock direction, and the second non-contact area NCA2 may be positioned in the 6 o'clock direction. The first to third non-contact areas NCA1, NCA2, and NCA3 may be arranged in the same row (e.g., on a same line in the first direction DR1).

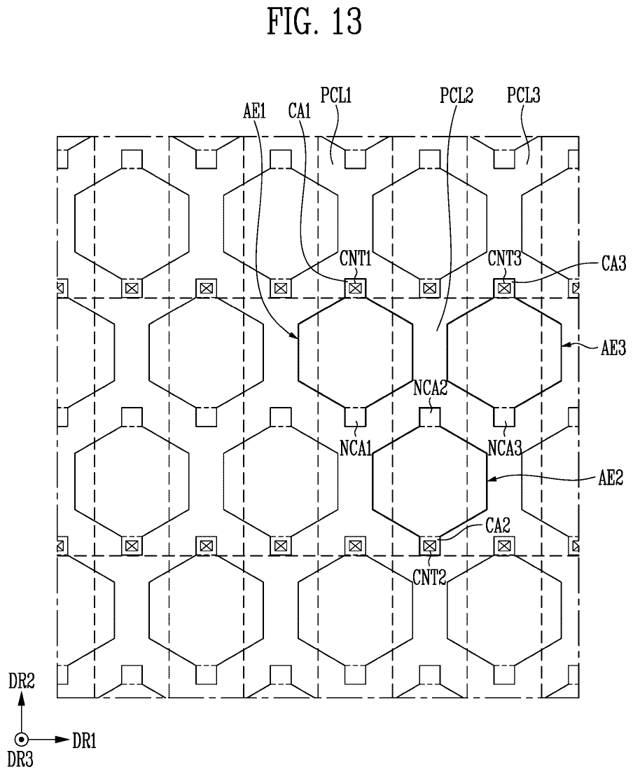

In FIG. 13, there are illustrated first to third anodes AE1, AE2, and AE3 corresponding to the second pixels PXL2 adjacent to each other. For example, there are illustrated the first anode AE1 and the third anode AE3 of one second pixel PXL2, and the second anode AE2 of an adjacent second pixel PXL2. Referring to FIG. 13, the first contact area CA1 may be positioned in the 12 o'clock direction, where the first anode AE1 may be electrically connected to the first pixel circuit layer PCL1 through the first contact hole CNT1. The second contact area CA2 may be positioned in the 6 o'clock direction, where the second anode AE2 may be electrically connected to the second pixel circuit layer PCL2 through the second contact hole CNT2. The third contact area CA3 may be positioned in the 12 o'clock direction, where the third anode AE3 may be electrically connected to the third pixel circuit layer PCL3 through the third contact hole CNT3.

The first to third non-contact areas NCA1, NCA2, and NCA3 may be respectively symmetrical to the first to third contact areas CA1, CA2, and CA3. The first non-contact area NCA1 and the third non-contact area NCA3 may be positioned in the 6 o'clock direction, and the second non-contact area NCA2 may be positioned in the 12 o'clock direction. The first to third non-contact areas NCA1, NCA2, and NCA3 may be arranged in the same row.

Referring to FIGS. 10 to 13, the first to third contact areas CA1, CA2, and CA3 may be alternately arranged in the first direction DR1 (or the row direction). The first to third non-contact areas NCA1, NCA2, and NCA3 may be alternately arranged in the first direction DR1 (or the row direction) at positions symmetrical to the first to third contact areas CA1, CA2, and CA3. The first to third contact areas CA1, CA2, and CA3 and the first to third non-contact areas NCA1, NCA2, and NCA3 may be respectively alternately arranged in the second direction DR2 (or the column direction). As such, because the first to third contact areas CA1, CA2, and CA3 and the first to third non-contact areas NCA1, NCA2, and NCA3 are repeatedly arranged at regular intervals, reflective color may be substantially uniformly outputted in all rows.

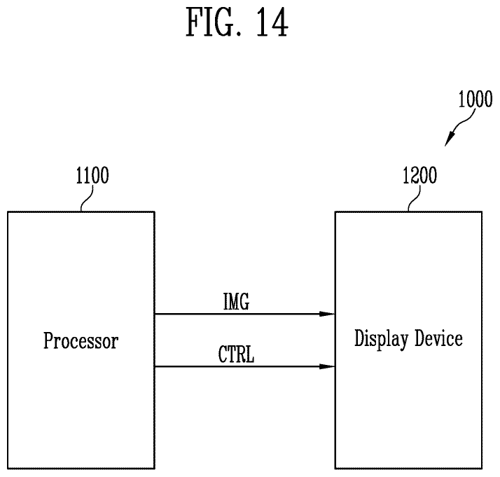

FIG. 14 is a block diagram of a display system in accordance with one or more embodiments.

Referring to FIG. 14, the display system 1000 may include a processor 1100 and a display device 1200.

The processor 1100 may perform various tasks and operations. In embodiments, the processor 1100 may include an application processor, a graphic processor, a microprocessor, a central processing unit (CPU), and so on. The processor 1100 may be connected to the other components of the display system 1000 through a bus system to control the components.

The processor 1100 may transmit image data IMG and a control signal CTRL to the display device 1200. The display device 1200 may display an image based on the image data IMG and the control signal CTRL. The display device 1200 may be configured in the same manner as the display device DD described with reference to FIG. 1. In this case, the image data IMG and the control signal CTRL may be provided as the input image data IMG and the control signal CTRL of FIG. 1, respectively.

The display system 1000 may include computing systems that provide an image display function, such as a smart watch, a mobile phone, a smart phone, a portable computer, a tablet personal computer (tablet PC), a watch phone, an automotive display, smart glasses, a portable multimedia player (PMP), a navigation system, or an ultra-mobile personal computer (UMPC). Furthermore, the display system 1000 may include at least one of a head-mounted display (HMD), a virtual reality (VR) device, a mixed reality (MR) device, or an augmented reality (AR) device.

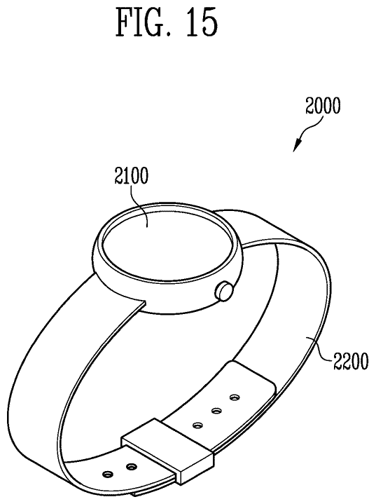

FIGS. 15 to 18 are perspective views of applications of a display system of FIG. 14.

Referring to FIG. 15, the display system 1000 of FIG. 14 may be applied to a smart watch 2000 including a display component 2100 and a strap 2200.

The smart watch 2000 may be a wearable electronic device. For example, the smart watch 2000 may have a structure in which the strap 2200 may be mounted on the wrist of the user. Here, the display system 1000 and/or the display device 1200 may be applied to the display component 2100, so that image data including time information can be provided to the user.

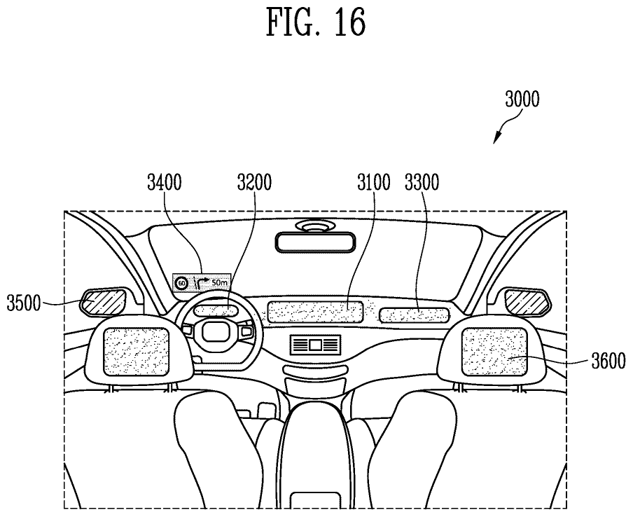

Referring to FIG. 16, the display system 1000 of FIG. 14 may be applied to an automotive display system 3000. Here, the automotive display system 3000 may include a computing system that is provided inside and/or outside a vehicle to provide image data.

For example, the display system 1000 and/or the display device 1200 may be applied to at least any one of an infotainment panel 3100, a cluster 3200, a co-driver display 3300, a head-up display 3400, a side mirror display 3500, or a rear seat display 3600, which may be provided in the vehicle.

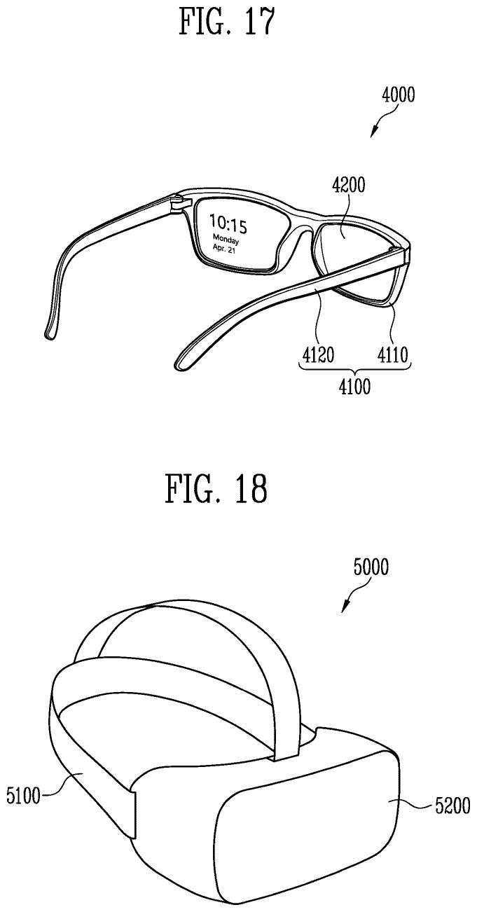

Referring to FIG. 17, the display system 1000 of FIG. 14 may be applied to smart glasses 4000. The smart glasses 4000 may be a wearable electronic device capable of being worn on the head of the user. For example, the smart glasses 4000 may be a wearable device for augmented reality.

The smart glasses 4000 may include a frame 4100 and a lens component 4200. The frame 4100 may include a housing 4110 which supports the lens component 4200, and a leg component 4120 enabling the user to wear the smart glasses. The leg component 4120 may be connected to the housing 4110 by a hinge, and thus can be folded or unfolded with respect to the housing 4110.

The frame 4100 may be equipped with a battery, a touch pad, a microphone, a camera, and the like. Furthermore, the frame 4100 may be equipped with a projector configured to output light, and a processor configured to control a light signal and the like.

The lens component 4200 may include an optical component configured to transmit or reflect light. For example, the lens component 4200 may include glass, transparent synthetic resin, and the like.

To enable the eyes of the user to perceive visual information, the lens component 4200 may reflect images based on an optical signal transmitted from the projector of the frame 4100 by a rear surface of the lens component 4200 (e.g., a surface facing the eyes of the user). For example, the user may perceive visual information, such as time and date displayed on the lens component 4200. Here, the projector and/or the lens component 4200 may be a kind of display device. The display device 1200 may be applied to the projector and/or the lens component 4200.

Referring to FIG. 18, the display system 1000 of FIG. 14 may be applied to a head-mounted display device 500.

The head-mounted display device 5000 may be a wearable electronic device, which can be worn on the head of the user. For example, the head-mounted display device 5000 may be a wearable device for virtual reality or mixed reality.

The head-mounted display device 5000 may include a head-mounted band 5100 and a display device reception casing 5200. The head-mounted band 5100 may be connected to the display device reception casing 5200. The head-mounted band 5100 may include a horizontal band and/or a vertical band to fasten the head-mounted display device 5000 to the head of the user. The horizontal band may enclose, or partially encircle, the sides of the head of the user, and the vertical band may enclose, or partially encircle, the top of the head of the user. However, the embodiments are not limited to the aforementioned example. For example, the head-mounted band 5100 may be implemented in the form of eyeglass frames, a helmet, and so on.

The display device reception casing 5200 may receive the display system 1000 and/or the display device 1200.

Various embodiments of the present disclosure provide a display device capable of removing a difference in reflective color between areas.

However, aspects of the present disclosure are not limited to those described above, and various other aspects would be understood by one of ordinary skill in the art within the spirit and scope of the present disclosure.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of the present disclosure. The embodiments may be combined to form additional embodiments.

What is claimed is:

1. A display device comprising:
a pixel circuit layer; and
an anode above the pixel circuit layer, and comprising:
a contact area overlapping a contact hole electrically connected with a connection pattern of the pixel circuit layer; and
a non-contact area that is symmetrical to the contact area.

2. The display device according to claim 1, wherein a surface area and a shape of the non-contact area are substantially identical to a surface area and a shape of the contact area.

3. The display device according to claim 1, wherein, in a plan view, the contact area is positioned in a 6 o'clock direction, and the non-contact area is positioned in a 12 o'clock direction.

4. The display device according to claim 1, wherein, in a plan view, the contact area is positioned in a 12 o'clock direction, and the non-contact area is positioned in a 6 o'clock direction.

5. The display device according to claim 1, wherein the anode further comprises an exposure area corresponding to a shape of an emission area.

6. The display device according to claim 5, wherein the shape of the emission area is substantially hexagonal.

7. The display device according to claim 1, wherein no contact hole is below the non-contact area.

8. A display device comprising:
a first anode comprising a first contact area overlapping a first contact hole electrically connected to a connection pattern of a first pixel circuit layer, and a first non-contact area that is symmetrical to the first contact area;
a second anode comprising a second contact area overlapping a second contact hole electrically connected to a connection pattern of a second pixel circuit layer, and a second non-contact area that is symmetrical to the second contact area; and
a third anode comprising a third contact area overlapping a third contact hole electrically connected to a connection pattern of a third pixel circuit layer, and a third non-contact area that is symmetrical to the third contact area.

9. The display device according to claim 8, wherein the first pixel circuit layer, the second pixel circuit layer, and the third pixel circuit layer are arranged in a row direction.

10. The display device according to claim 9, wherein the first anode and the third anode are arranged in the row direction, and the second anode is arranged in a diagonal direction from the first anode or the third anode.

11. The display device according to claim 8, wherein the first contact area, the second contact area, and the third contact area are arranged in a same row.

12. The display device according to claim 11, wherein, in a plan view, the first contact area and the third contact area are positioned in a 6 o'clock direction, and the second contact area is positioned in a 12 o'clock direction.

13. The display device according to claim 12, wherein, in a plan view, the first non-contact area and the third non-contact area are positioned in the 12 o'clock direction, and the second non-contact area is positioned in the 6 o'clock direction.

14. The display device according to claim 11, wherein, in a plan view, the first contact area and the third contact area are positioned in a 12 o'clock direction, and the second contact area is positioned in a 6 o'clock direction.

15. The display device according to claim 14, wherein, in a plan view, the first non-contact area and the third non-contact area are positioned in the 6 o'clock direction, and the second non-contact area is positioned in the 12 o'clock direction.

16. The display device according to claim 8, wherein the first non-contact area, the second non-contact area, and the third non-contact area are arranged in a same row.

17. The display device according to claim 16, wherein, in a plan view, the first non-contact area and the third non-contact area are positioned in a 12 o'clock direction, and the second non-contact area is positioned in a 6 o'clock direction.

18. The display device according to claim 17, wherein, in a plan view, the first contact area and the third contact area are positioned in a 6 o'clock direction, and the second contact area is positioned in a 12 o'clock direction.

19. The display device according to claim 16, wherein, in a plan view, the first non-contact area and the third non-contact area are positioned in a 6 o'clock direction, and the second non-contact area is positioned in a 12 o'clock direction.

20. The display device according to claim 19, wherein, in a plan view, the first contact area and the third contact area are positioned in the 12 o'clock direction, and the second contact area is positioned in the 6 o'clock direction.
